(19) United States
(12) Patent Application Publication
(10) Pub. No.: US 2015/0311305 A1
(43) Pub. Date: Oct. 29, 2015

(54) SPIN MOSFET

(71) Applicant: KABUSHIKI KAISHA TOSHIBA, Minato-ku (JP)

(72) Inventors: Mizue ISHIKAWA, Yokohama (JP); Tomoaki INOKUCHI, Yokohama (JP); Hideyuki SUGIYAMA, Kawasaki (JP); Tetsufumi TANAMOTO, Kawasaki (JP); Yoshiaki SAITO, Kawasaki (JP)

(73) Assignee: KABUSHIKI KAISHA TOSHIBA, Minato-ku (JP)

(21) Appl. No.: 14/793,173

(22) Filed: Jul. 7, 2015

Related U.S. Application Data
(63) Continuation of application No. PCT/JP2014/067657, filed on Jul. 2, 2014.

(30) Foreign Application Priority Data
Sep. 20, 2013 (JP) 2013-195731

(51) Int. Cl. H01L 29/45; H01L 29/82; H01L 29/08; H01L 29/66

(52) U.S. Cl. CPC H01L 29/45; H01L 29/66984; H01L 29/82; H01L 29/0847

(57) ABSTRACT

An MOSFET according to an embodiment includes: a source and drain electrodes each including a magnetic layer; a gate insulating film; and a gate electrode provided on the gate insulating film, a junction resistance on a source electrode side being greater than that on a drain electrode side, when the MOSFET is of n-channel type, the source and drain electrodes contain a magnetic material in which a gap energy between a Fermi surface and a valence band maximum is greater than that between the Fermi surface and a conduction band minimum, and when the spin-transfer-torque switching MOSFET is of p-channel type, the source and drain electrodes containing a magnetic material in which a gap energy between a Fermi surface and a valence band maximum is less than that between the Fermi surface and a conduction band minimum.

### CROSS REFERENCE TO RELATED APPLICATIONS

This application is a continuation of International Application No. PCT/JP2014/067657, filed on Jul. 2, 2014, which is based upon and claims the benefit of priority from the prior Japanese Patent Application No. 2013-195731, filed on Sep. 20, 2013, the entire contents of which are incorporated herein by reference.

### FIELD

Embodiments described herein relate generally to metal-oxide-semiconductor field-effect transistors (MOSFETs) with consideration given to electric field effect (“field effect”).

### BACKGROUND

Application of spintronics, represented by magnetic storage devices (magnetic random access memories (MRAMs)) including tunneling magnetoresistance effect (TMR) elements as storage elements, to LSIs of the next generation is attracting attention.

Recently, the possibilities of using not only MRAMs but also various other devices as spin devices have been expanded. Spin-transfer-torque switching metal-oxide-semiconductor field-effect transistors (hereinafter also referred to spin MOSFETs) are among such other devices.

A spin MOSFET is a common MOSFET containing a ferromagnetic material in its source electrode and drain electrode, which adds a spin degree of freedom to the carrier. With this function, spin MOSFETs are expected to be applied to reconfigurable circuits such as field programmable gate arrays (FPGAs).

A high magnetocurrent ratio (“MC ratio”) is required to achieve a spin MOSFET. The MC ratio can be defined as follows:

$$MC Ratio = \frac{{I}_{p} - {I}_{ap}}{{I}_{ap}} \times 100 [ \% ]$$

where Ip is a current flowing between the source electrode and the drain electrode through the channel when the spin direction of the ferromagnetic material in the source electrode is parallel to that in drain electrode, and Iap is a current flowing between the source electrode and the drain electrode through the channel when the spin direction of the ferromagnetic material in the source electrode is antiparallel to that in the drain electrode.

It has become evident that the field effect exerts an influence on the MC ratio. Spin MOSFETs that are capable of achieving a high MC ratio in consideration of the field effect are desired.

### BRIEF DESCRIPTION OF THE DRAWINGS

FIG. 1 is band gap diagram showing characteristics of a ferromagnetic material included in a spin MOSFET according to embodiments.

FIG. 2 is a cross-sectional view of a spin MOSFET according to a first embodiment.

FIG. 3 is a top view of a specific example of the spin MOSFET according to the first embodiment.

FIG. 4 is a top view of another specific example of the spin MOSFET according to the first embodiment.

FIG. 5 is a cross-sectional view of a spin MOSFET according to a first modification of the first embodiment.

FIG. 6 is an explanatory view of a voltage-controlled writing method.

FIG. 7 is a cross-sectional view of a method of manufacturing the spin MOSFET according to the first embodiment.

FIG. 8 is an explanatory cross-sectional view of the method of manufacturing the spin MOSFET according to the first embodiment.

FIG. 9 is a cross-sectional view of a spin MOSFET according to a second embodiment.

FIG. 10 is a cross-sectional view of a spin MOSFET according to a modification of the second embodiment.

FIG. 11 is an explanatory cross-sectional view of a method of manufacturing the spin MOSFET according to the second embodiment.

FIG. 12 is an explanatory cross-sectional view of the method of manufacturing the spin MOSFET according to the second embodiment.

FIG. 13 is an explanatory cross-sectional view of the method of manufacturing the spin MOSFET according to the second embodiment.

FIG. 14 is a cross-sectional view of a spin MOSFET according to a third embodiment.

FIG. 15 is an explanatory cross-sectional view of the spin MOSFET according to the third embodiment.

FIG. 16 is an explanatory cross-sectional view of a method of manufacturing the spin MOSFET according to the third embodiment.

FIG. 17 is an explanatory cross-sectional view of the method of manufacturing the spin MOSFET according to the third embodiment.

FIG. 18 is a cross-sectional view showing a film structure of a device according to Example 1.

FIG. 19 is a cross-sectional view showing a structure of the device according to Example 1.

FIG. 20 is a diagram showing the dependence of measured Local signals on the bias voltage in Example 1.

FIG. 21 is a diagram showing the bias voltage and the density of state on the source electrode side and the drain electrode side of a spin MOSFET according to Example 2.

FIG. 22 is a diagram showing the relationship between the bias voltage and the spin polarization estimated from the density of state of a Heusler alloy Co₂FeAl₁₋ₓSiₓ.

FIG. 23 is a diagram showing the relationship between the bias voltage and the spin polarization estimated from the density of state of a Heusler alloy Co₂Mn₁₋ₓFeₓSi.

### DETAILED DESCRIPTION

An MOSFET according to one or more embodiments includes: a semiconductor layer; a source electrode and a drain electrode each including a magnetic layer provided on the semiconductor layer so as to be separated from each other, a junction resistance between the source electrode and the semiconductor layer being greater than a junction resistance between the drain electrode and the semiconductor layer; a gate insulating film provided on a region of the semiconductor layer to serve as a channel between the source electrode and the drain electrode; and a gate electrode provided on the gate insulating film, wherein the MOSFET is of n-channel type, and the source electrode and the drain electrode contain a ferromagnetic material in which a gap energy between a Fermi surface and a valence band maximum of a valence band is greater than a gap energy between the Fermi surface and a conduction band minimum of a conduction band, or wherein the MOSFET is of p-channel type, and the source electrode and the drain electrode contain a magnetic material in which a gap energy between a Fermi surface and a valence band maximum of a valence band is less than a gap energy between the Fermi surface and a conduction band minimum of a conduction band.

Before embodiments are described, how the present invention has been reached will be described.

Spin-transfer-torque switching MOSFETs (hereinafter also referred to spin MOSFETs) have been evaluated with conditions not considering the field effect. However, in reality, each spin MOSFET has an electric field. Therefore, it is needed to study optimum device structures and ferromagnetic materials for spin MOSFETs in consideration of the field effect.

The present inventors evaluated spin MOSFETs in consideration of the field effect. As a result, it has become evident that the MC ratio, which is one of the important indicators of the memory function, is dependent on the electric field. For example, the present inventors have found in evaluating Local signal, which is often used to evaluate the MC ratio, that when spin electrons are caused to flow from the source side to the drain side, the Local signal increases, i.e., a high MC ratio can be obtained, if the electric field on the source side is greater than that on the drain side. In this specification, the source electrode in an n-channel spin MOSFET is defined to inject electrons to a semiconductor, and the drain electrode is defined to extract electrons from the semiconductor. The source electrode in a p-channel spin MOSFET is defined to inject holes to a semiconductor, and the drain electrode is defined to extract holes from the semiconductor.

The present inventors then considered that a spin MOSFET with a higher MC ratio may be achieved by obtaining a device structure in which the junction resistance on the side where majority carriers are injected is greater than the junction resistance on the detection side. The “junction resistance” herein means a junction resistance in a direction from each electrode to a semiconductor layer or from the semiconductor layer to each electrode when the source electrode and the drain electrode are formed on the semiconductor layer.

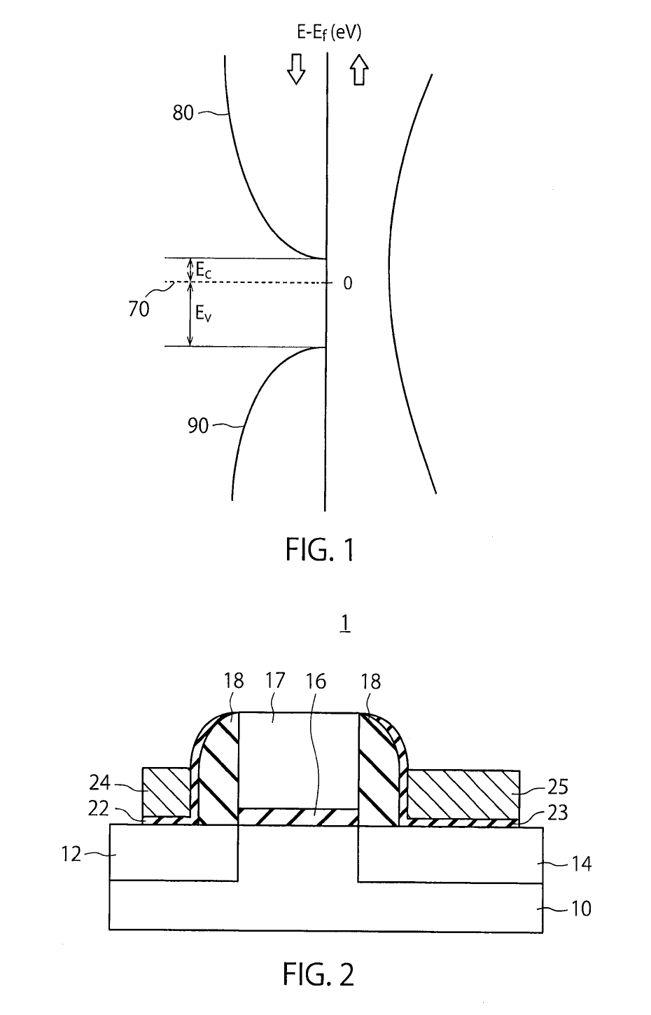

The present inventors have further found in evaluating spin transfer torque efficiency and detection efficiency that the density of state (DOS) of a ferromagnetic material has an influence on these efficiencies. This means that the spin injection and detection efficiencies are varied by the field effect. The MC ratio is susceptible to the spin polarization estimated from the density of state of the ferromagnetic material. Since the spin polarization estimated from the DOS is dependent on the electric field, a ferromagnetic material showing a high spin polarization value in a high electric field on the injection side is required in consideration the dependence of the MC ratio on the field effect. The present inventors therefore considered that if a ferromagnetic material in which the gap energy Ev between the Fermi surface 70 and the valence band maximum of the valence band 90 is greater than the gap energy Ec between the Fermi surface 70 and the conduction band minimum of the conduction band 80 as shown in FIG. 1 is used to form the electrodes of an n-channel spin MOSFET, a high spin polarization may be maintained and a high MC ratio may be achieved even under the influence of the field effect. Specific examples of the ferromagnetic material will be described in the descriptions of embodiments. Conversely, in the case of a p-channel spin MOSFET, a ferromagnetic material in which the gap energy Ev between the Fermi surface 70 and the valence band maximum of the valence band 90 is less than the gap energy Ec between the Fermi surface 70 and the conduction band minimum of the conduction band 80 is employed.

It is concluded from the above that in order to achieve a high MC ratio in a spin MOSFET in consideration of the field effect, an optimum ferromagnetic material in consideration of the field effect is needed as well as an optimum device structure.

The present inventors have found a preferable spin MOSFET structure for achieving a high MC ratio based on the foregoing. The structure will be described below with reference to embodiments.

Embodiments will now be described with reference the accompanying drawings.

### First Embodiment

A spin MOSFET according to a first embodiment will be described. FIG. 2 is a cross-sectional view showing a structure of a spin MOSFET according to the first embodiment. The spin MOSFET 1 according to the first embodiment includes impurity regions 12, 14 to serve as a source region and a drain region disposed in a semiconductor layer 10 so as to be separated from each other, a gate insulating film 16 disposed on a region in the semiconductor layer 10 to serve as a channel region between the source region 12 and the drain region 14, a gate electrode 17 disposed on the gate insulating film 16, a gate sidewall 18 of an insulating material disposed on a side portion of the gate electrode 17, a source electrode 24 of a ferromagnetic layer disposed on the source region 12 via a tunnel insulating film 22, and a drain electrode 25 of a ferromagnetic layer disposed on the drain region 14 via a tunnel insulating film 23. If the spin MOSFET 1 is of n-channel type, the semiconductor layer 10 is a p-type semiconductor layer and the source region 12 and the drain region 14 are n⁺ impurity regions. If the spin MOSFET 1 is of p-channel type, the semiconductor layer 10 is an n-type semiconductor layer, and the source region 12 and the drain region 14 are p⁺ impurity regions.

The junction area of the source electrode 24 is less than that of the drain electrode 25 in the first embodiment in order to have a greater junction resistance on the source electrode 24 side than the drain electrode 25 side. Since the junction area of the source electrode 24 is less than that of the drain electrode 25, the electric field on the source side becomes greater than the electric field on the drain side. As a result, the MC ratio is improved due to the influence of the field effect, as the present inventors have found. The MC ratio may be improved if the ratio of the junction area of the drain electrode 25 to the junction area of the source electrode 24 is 1.1 or more. The ratio is more preferably 1.3 or more. Therefore, the junction resistance on the source electrode 24 side is preferably 1.1 or more, and more preferably 1.3 or more, times the junction resistance on the drain electrode 25 side.

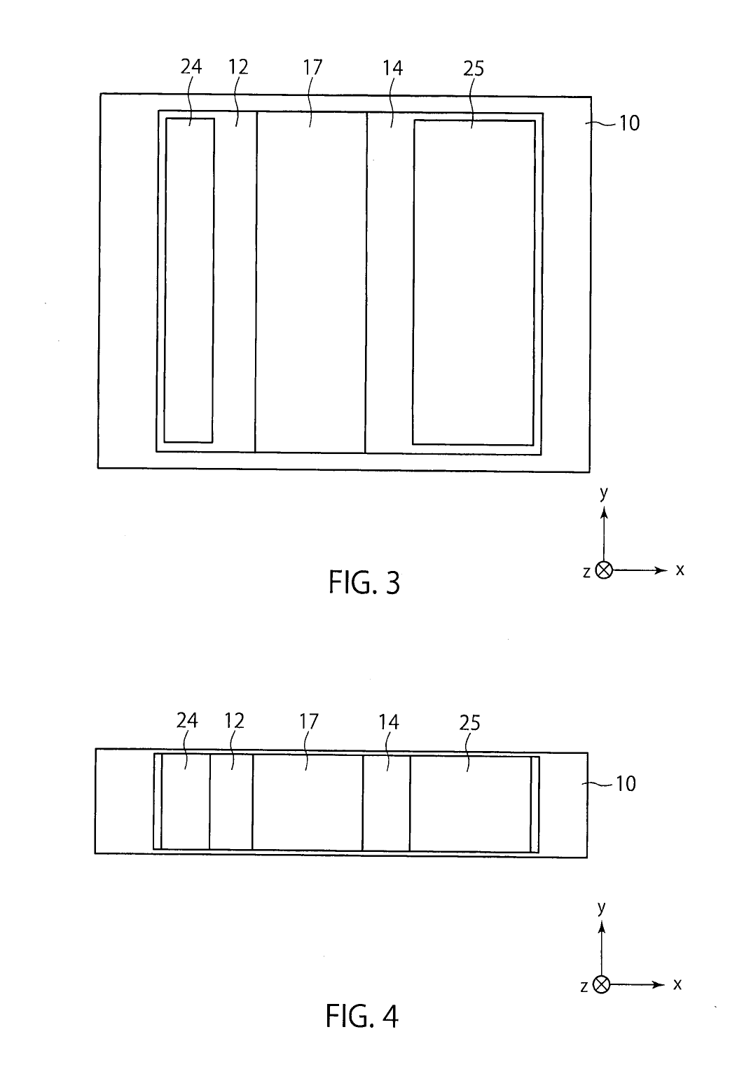

In order to reduce the junction area of the source electrode 24, the length in a direction parallel to the channel (the x-axis direction in FIGS. 3 and 4) is preferably shortened. This makes it possible to maintain the distance between the source electrode 24 and the drain electrode 25 to be constant and the shortest in the channel direction. As a result, the spin relaxation is kept constant without being dependent on the location, and unnecessary spin relaxation can be prevented. FIGS. 3 and 4 are top views in each of which the gate sidewall 18 is omitted.

The impurity concentration of the source region 12 or the drain region 14 immediately below the source electrode 24 or the drain electrode 25 is preferably high in order to reduce the resistance, and more preferably a concentration with which a depletion layer is formed in order to have a high MC ratio. This makes it possible to increase the electric field on the source electrode 12 side further relative to the electric field on the drain electrode 14 side, thereby achieving a high MC ratio.

Next, the operation of the spin MOSFET according to the first embodiment will be described below. A case where the direction of magnetization in the ferromagnetic layer to serve as the source electrode 24 is switchable, and the direction of magnetization in the ferromagnetic layer to serve as the drain electrode 25 is fixed will be described regarding the first embodiment. The directions, however, may be reversed, and the direction of magnetization in the ferromagnetic layer to serve as the source electrode 24 may be fixed, and the direction of magnetization in the ferromagnetic layer to serve as the drain electrode 25 may be switchable. The term “changeable” with respect to the direction of magnetization herein means that if a write current is caused to flow through a ferromagnetic layer, the direction of magnetization can be changed before and after the write operation. The term “fixed” with respect to the direction of magnetization means that the direction of magnetization is not changed before and after the write operation. The direction magnetization of each of the ferromagnetic layers 24, 25 is assumed to be parallel or perpendicular to the film plane. The “film plane” here means a plane extending in a direction perpendicular to the direction along which the ferromagnetic layers are stacked.

Next, the write method will be described below.

A write method will be described in a case where the magnetization direction of the ferromagnetic layer to serve as the source electrode 24 is caused to be parallel to (in the same direction as) the magnetization direction of the ferromagnetic layer to serve as the drain electrode 25 when the magnetization direction of the ferromagnetic layer to serve as the source electrode 24 in the initial state is antiparallel to (in the opposite direction to) the magnetization direction of the ferromagnetic layer to serve as the drain electrode 25. A voltage is applied to the gate electrode 17 to turn ON the spin MOSFET 1. Subsequently, a write current is caused to flow from the source electrode 24 to the drain electrode 25 via the source region 12, the tunnel insulating film 22, the channel region, the drain region 14, and the tunnel insulating film 23. At this time, an electron current flows in the opposite direction as the write current. Electrons passing through the drain electrode 25 are spin polarized by the ferromagnetic layer to serve as the drain electrode 25. The spin-polarized electrons flows from the drain electrode 25 to the source electrode 24 via the tunnel insulating film 23, the drain region 14, the channel region, the source region, and the tunnel insulating film 22, and applies a spin transfer torque to the ferromagnetic layer to serve as the source electrode 24, thereby causing the magnetization direction of the ferromagnetic layer to serve as the source electrode 24 to be in the same direction as the magnetization direction of the ferromagnetic layer to serve as the drain electrode 25.

A write method in a case where the magnetization direction of the ferromagnetic layer to serve as the source electrode 24 is caused to be antiparallel to the magnetization direction of the ferromagnetic layer to serve as the drain electrode 25 when the magnetization direction of the ferromagnetic layer to serve as the source electrode 24 in the initial state is parallel to the magnetization direction of the ferromagnetic layer to serve as the drain electrode 25 is performed in the following manner. A voltage is applied to the gate electrode 17 to turn ON the spin MOSFET 1. Subsequently, a write current is caused to flow from the drain electrode 25 to the source electrode 24 via the tunnel insulating film 23, the drain region 14, the channel region, the source region 12, and the tunnel insulating film 22. In this case, electrons flow from the source electrode 24 to the drain electrode 25 via the tunnel insulating film 22, the source region 12, the channel region, the drain region 14, and the tunnel insulating film 23. Electrons passing through the source electrode 24 are spin-polarized. The spin-polarized electrons flow from the source electrode 24 to the drain electrode 25 via the tunnel insulating film 22, the source region 12, the channel region, the drain region 14, and the tunnel insulating film 23. The spin-polarized electrons, the spin direction of which is parallel to the magnetization direction of the ferromagnetic layer to serve as the drain electrode 25, pass through the ferromagnetic layer to serve as the drain electrode 25. The spin-polarized electrons, the spin direction of which is antiparallel to the magnetization direction of the ferromagnetic layer to serve as the drain electrode 25, are reflected at the interface between the tunnel insulating film 23 and the ferromagnetic layer to serve as the drain electrode 25, and flow to the source electrode 24 via the drain region 14, the channel region, the source region 12, and the tunnel insulating film 22 to apply a spin torque to the ferromagnetic layer to serve as the source electrode 24, thereby causing the magnetization direction of the ferromagnetic layer to serve as the source electrode 24 to be antiparallel to the magnetization direction of the ferromagnetic layer to serve as the drain electrode 25.

Examples of the semiconductor material of the semiconductor layer 10 may include Si, Ge, SiGe, GaAs, or InGaAs.

A conductive material such as a metal and a semiconductor including polycrystalline silicon may be used to form the gate electrode 17.

Examples of a material to form the tunnel insulating films 22, 23 include an alkaline earth oxide with a NaCl structure (for example, MgO), Al₂O₃, MgAl₂O₄, SiO₂, ZnO, (MgₓZn₁₋ₓ)O, AlNx, HfO₂, Zr₂O₃, Cr₂O₃, TiO₂, or SrTiO₃. MgO is more preferable since an improvement of the MC ratio can be expected by using the spin filter effect of MgO.

If the spin MOSFET 1 is of n-channel type, an ferromagnetic material in which the gap energy Ev between the Fermi surface 70 and the valence band maximum of the valence band 90 is greater than the gap energy Ec between the Fermi surface 70 and the conduction band minimum of the conduction band 80 as described above with reference to FIG. 1 is used to form the ferromagnetic layers of the source electrode 24 and the drain electrode 25.

If the spin MOSFET 1 is of p-channel type, an ferromagnetic material in which the gap energy Ev between the Fermi surface 70 and the valence band maximum of the valence band 90 is less than the gap energy Ec between the Fermi surface 70 and the conduction band minimum of the conduction band 80 is used to form the ferromagnetic layers of the source electrode 24 and the drain electrode 25.

If the spin MOSFET 1 is of n-channel type, at least one material selected from the group consisting of Co₂FeAl₁₋ₓSiₓ (0.5≦x≦1.0), Co₂Mn₁₋ₓFeₓSi (0.25≦x≦1.0), Co₂MnₓTi₁₋ₓGe (0≦x≦0.5), Co₂Cr₁₋ₓFeₓAl (0.75≦x≦1.0), Mn₂CoSn, and Co₂TiAl is preferably used as the ferromagnetic material.

If the spin MOSFET 1 is of p-channel type, at least one material selected from the group consisting of Co₂FeAl₁₋ₓSiₓ (0≦x<0.5), Co₂Mn₁₋ₓFeₓSi (0≦x<0.25), Co₂MnₓTi₁₋ₓGe (0.5<x≦1.0), Co₂Cr₁₋ₓFeₓAl (0≦x<0.75), and CoFeMnX (where X is at least one element selected from the group consisting of Al, Si, Ge, and Ga) is preferably used. A spin MOSFET with a high spin polarization can be achieved by using the above ferromagnetic materials.

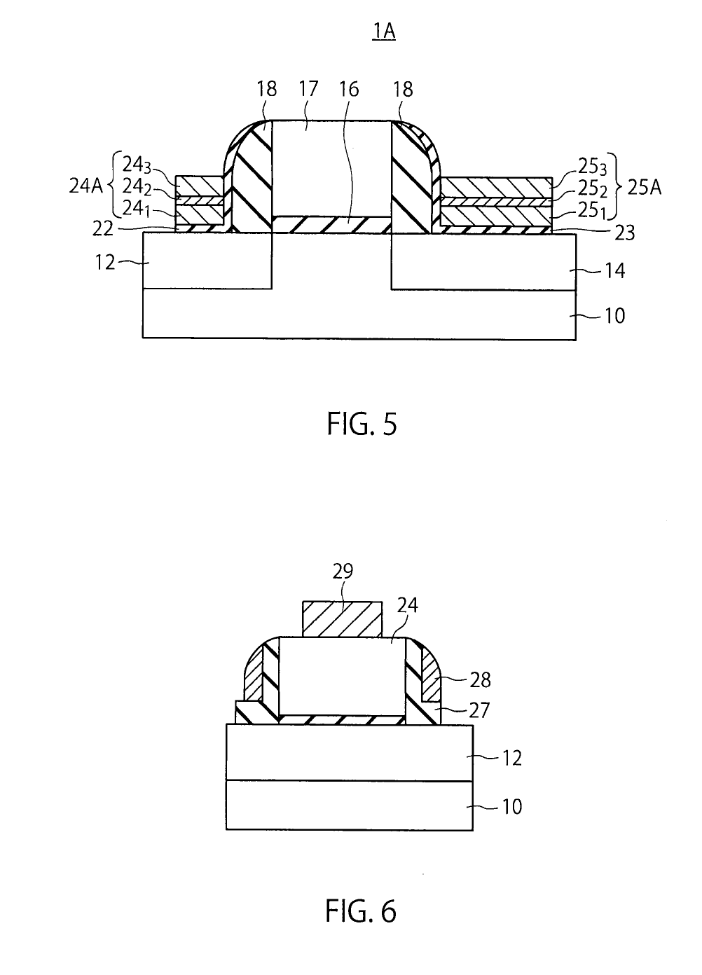

A giant magnetoresistance (GMR) element may be employed as at least one of the source electrode 24 and the drain electrode 25. For example, GMR elements may be employed as a source electrode 24A and a drain electrode 25A of a spin MOSFET 1A according to a first modification of the first embodiment shown in FIG. 5. The spin MOSFET 1A according to the modification is obtained by replacing the source electrode 24 and the drain electrode 25 of the spin MOSFET 1 according to the first embodiment shown in FIG. 2 with the source electrode 24A and the drain electrode 25A. The source electrode 24A is a GMR element including a ferromagnetic film 24₁ disposed on the source region 12 side, a nonmagnetic metal film 24₂ disposed on the ferromagnetic film 24₁, and a ferromagnetic film 24₃ disposed on the nonmagnetic metal film 24₂. The drain electrode 25A is a GMR element including a ferromagnetic film 25₁ disposed on the drain region 14 side, a nonmagnetic metal film 25₂ disposed on the ferromagnetic film 25₁, and a ferromagnetic film 25₃ disposed on the nonmagnetic metal film 25₂. The resistance between the source electrode 24A and the drain electrode 25A through the channel varies depending on whether the magnetization direction of the ferromagnetic film 24₁ included in the source electrode 24A disposed on the source region 12 side is parallel or antiparallel to the magnetization direction of the ferromagnetic film 25₁ included in the drain electrode 25A disposed on the drain region 14 side.

Thus, a GMR element having a multilayer structure including a ferromagnetic film, a nonmagnetic metal film, and a ferromagnetic film, which is capable of switching the spin direction, is preferably used to form the source electrode and the drain electrode. A high GMR ratio can be obtained by using a Heusler alloy or CoFe alloy to form the ferromagnetic films, and Ag or Cu to form the nonmagnetic metal films. The Heusler alloy is not limited to that used to form the ferromagnetic film disposed on the tunnel insulating film as long as it has a high spin polarization. The magnetization of the ferromagnetic film may be parallel or perpendicular to the film plane.

Using GMR elements makes it possible to use the GMR ratio as the MC ratio. As a result, a spin MOSFET with a high MC ratio can be obtained.

A voltage-controlled writing method using a ferroelectric material may be applied to switch the spin direction instead of the spin transfer torque switching method. In this case, a ferroelectric layer 27 is disposed on a side portion of the source electrode 24 formed of a ferromagnetic layer, a nonmagnetic conductive layer 28 is disposed on the ferroelectric layer 27 on the opposite side to the source electrode 24, and an electrode 29 is disposed on the source electrode 24 as in a second modification of the first embodiment shown in FIG. 6. Specifically, the nonmagnetic conductive layer 28 is disposed on the side portion of the source electrode 24, and the ferroelectric layer 27 is disposed between the source electrode 24 and the nonmagnetic conductive layer 28. The magnetization direction at the interface of the ferromagnetic layer 24 with the ferroelectric layer 27 is switched by applying a positive (negative) voltage between the electrode 29 and the nonmagnetic conductive layer 28, or between the source region 12 and the nonmagnetic layer 28 of the source electrode having the above structure. Returning the applied voltage to zero causes the switched magnetization direction of the ferromagnetic layer 24 to be maintained. Thereafter, the magnetization direction of the interface of the ferromagnetic layer 24 with the ferroelectric layer 27 is switched if a negative (positive) voltage is applied between the electrode 29 and the nonmagnetic conductive layer 28, or between the source region 12 and the nonmagnetic conductive layer 28. Returning the applied voltage to zero causes the switched magnetization direction of the ferromagnetic layer 24 to be maintained. The magnetization direction of the ferromagnetic layer in the source electrode 24 can be switched by controlling voltage in this manner.

The tunnel insulating films 22, 23 disposed at the interfaces between the semiconductor layer 10 and the ferromagnetic layers 24, 25 in the first embodiment as shown in FIG. 2 may be omitted if the conductance mismatch between the semiconductor layer 10 and the ferromagnetic layers 24, 25 can be solved.

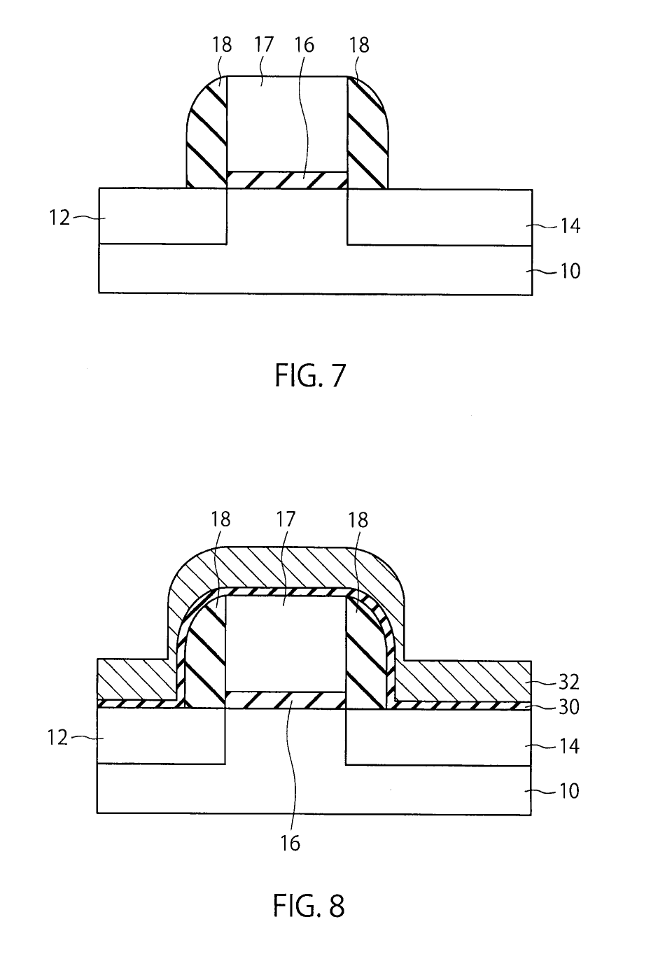

Next, a method of manufacturing a spin MOSFET according to the first embodiment will be described below with reference to FIGS. 7 to 9.

First, an insulating material film is formed on a semiconductor layer 10, and a gate electrode material film is formed on the insulating material film, as shown in FIG. 7. Subsequently, the gate electrode material film and the insulating material film are patterned in the shape of gate electrode to form a gate electrode 17 and a gate insulating film 16. Thereafter, an impurity is injected to the semiconductor layer 10 using the gate electrode 17 as a mask, and a heat treatment for activation is performed, thereby forming a source region 12 and a drain region 14. Then, a gate sidewall 18 of an insulating material is formed on a side portion of the gate electrode 17. The source region 12 and the drain region 14 may be formed by injecting the impurity to the semiconductor layer 10 and performing activation after the gate sidewall 18 is formed.

Thereafter, native oxide films on the source region 12 and the drain region 14 are removed, and an insulating material film 30 and a ferromagnetic material film 32 are sequentially formed (FIG. 8).

Subsequently, a resist (not shown) is applied onto the semiconductor layer 10, and a resist pattern is formed by a lithographic technique, in which an area for a source electrode is smaller than an area for a drain electrode. The resist pattern is used as a mask to pattern the ferromagnetic material film 32 and the insulating material film 30 by reactive ion etching (RIE) or milling to form a source electrode 24 and a drain electrode 25. A tunnel insulating film 22 is formed between the source electrode 24 and the source region 12, and a tunnel insulating film 23 is formed between the drain electrode 25 and the drain region 14 at this time.

Finally, a contact electrode (not shown) is formed on each of the ferromagnetic layers 24, 25 and the gate electrode 17 to complete a spin MOSFET.

As described above, according to the first embodiment, a spin MOSFET with a high MC ratio can be obtained.

### Second Embodiment

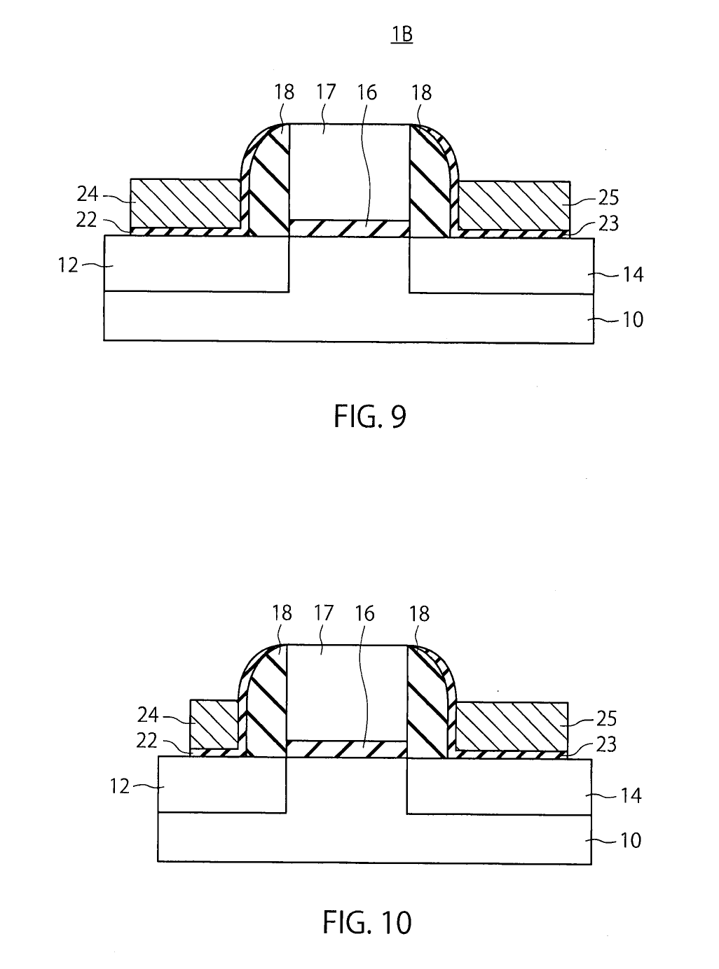

FIG. 9 shows a cross-sectional view of a spin MOSFET according to a second embodiment. The spin MOSFET 1B according to the second embodiment differs from the spin MOSFET 1 according to the first embodiment shown in FIG. 2 in the following two points. First, the junction area of the source electrode 24 is equal to the junction area of the drain electrode 25. Second, the impurity concentration in the source region 12 is lower than that in the drain region 14. Specifically the impurity concentration in the impurity region to serve as the source region 12 immediately below the source electrode 24 is set to be on the order of 10¹⁹/cm³ in order to cause the junction resistance on the source electrode to be greater than the junction resistance on the drain electrode in the spin MOSFET 1B according to the second embodiment. This is lower than a generally-called high impurity concentration (on the order of 10²⁰/cm³) of an ordinary source region. The width of the depletion layer in the source region 12 can be increased in this manner. This causes the junction resistance among the source electrode 24, the tunnel insulating film 22, the source region 12, and the channel to be greater than that on the drain electrode side, and the MC ratio to be improved due to the influence of the field effect found by the present inventors. The impurity concentration of the low concentration impurity region is preferably 1×10¹⁷/cm³ or more and 3×10²⁰/cm³ or less.

In the second embodiment, the impurity concentration of the source region 12 is made lower. Accordingly, the junction area of the source electrode 24 is set to be equal to that of the drain electrode 25. However, the junction area of the source electrode 24 may be smaller than that of the drain electrode 25 as in a modification of the second embodiment shown in FIG. 10. A smaller junction area in the source electrode 24 is more preferable if the field effect is considered since a higher MC ratio may be obtained.

The low concentration impurity region may be disposed in each of the source region 12 and the drain region 14, but it is more preferable that the low concentration impurity region is formed only in the source region 12, and a high concentration impurity region is formed in the drain region 14 as in the second embodiment.

The power consumption may be lowered by reducing the entire resistance of the spin MOSFET with the structure according to the second embodiment.

If the spin MOSFET 1B in the second embodiment is of n-channel type, a ferromagnetic material in which the gap energy Ev between the Fermi surface 70 and the valence band maximum of the valence band 90 is greater than the gap energy Ec between the Fermi surface 70 and the conduction band minimum of the conduction band 80 as described with reference to FIG. 1 is used to form the ferromagnetic layers of the source electrode 24 and the drain electrode 25 as in the case of the first embodiment. If the spin MOSFET 1B is of p-channel type, a ferromagnetic material in which the gap energy Ev between the Fermi surface 70 and the valence band maximum of the valence band 90 is lower than the gap energy Ec between the Fermi surface 70 and the conduction band minimum of the conduction band 80 is used to form the ferromagnetic layers of the source electrode 24 and the drain electrode 25.

A giant magnetoresistance (GMR) element may be used to form at least one of the source electrode 24 and the drain electrode 25 as in the case of the modification of the first embodiment shown in FIG. 5. The GMR element is more preferable since it can also be used to switch the spin direction. A spin MOSFET with a higher MC ratio can be obtained by using the GMR element since a higher spin polarization can be maintained.

A voltage-controlled writing method using a ferroelectric material may be employed to switch the spin direction instead of the spin transfer torque switching method. A source electrode with the structure of the second modification according to the first embodiment shown in FIG. 6 is used in this case.

The tunnel insulating films 22, 23 disposed at the interfaces between the semiconductor layer 10 and the ferromagnetic layers 24, 25 in the second embodiment shown in FIG. 9 may be omitted if the conductance mismatch between the semiconductor layer 10 and the ferromagnetic layers 24, 25 can be solved.

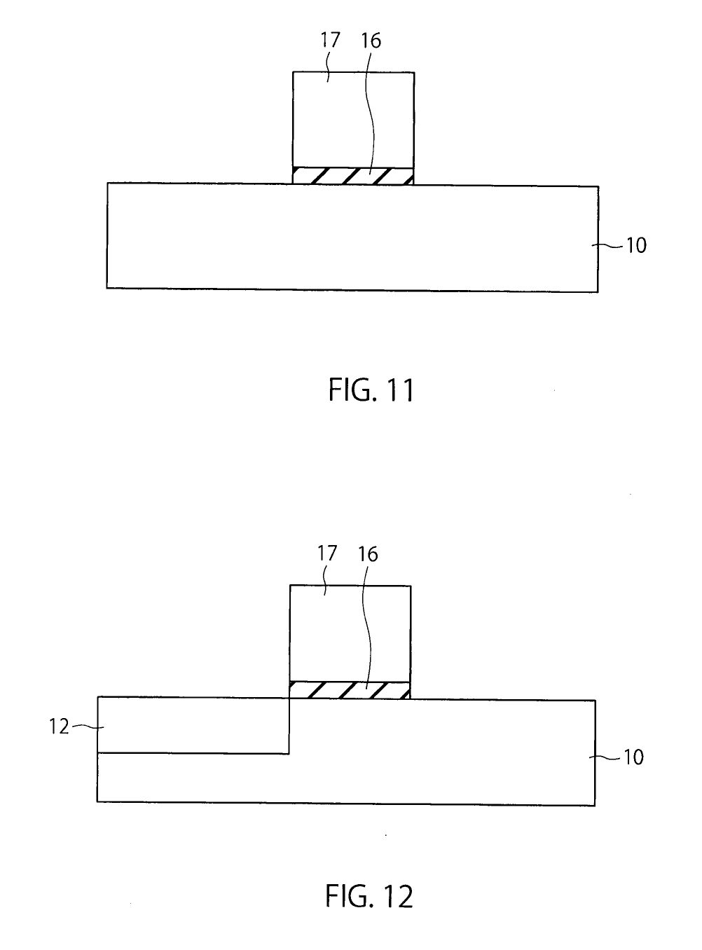

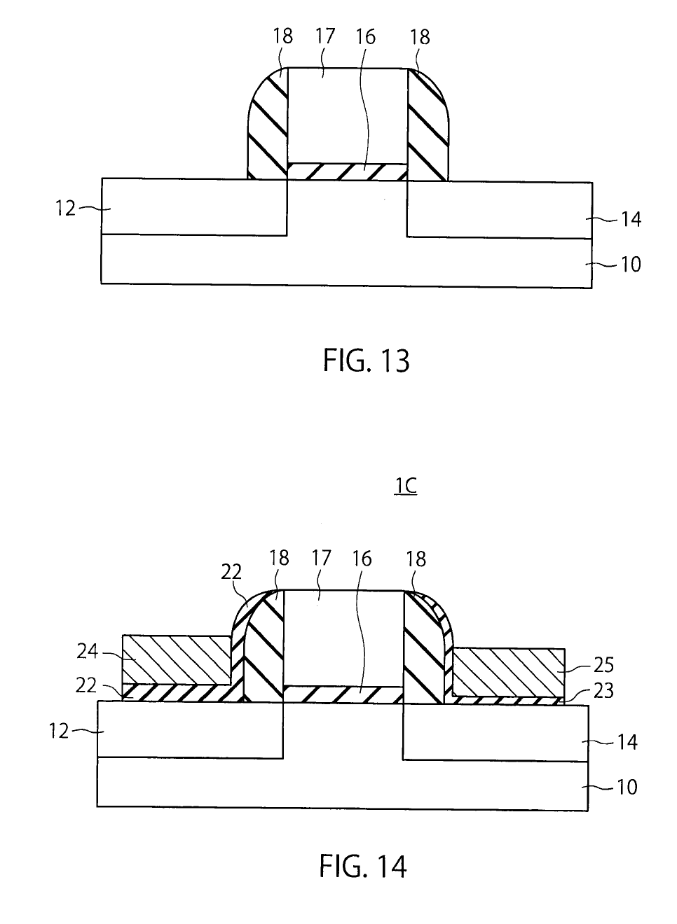

Next, a method of manufacturing the spin MOSFET according to the second embodiment will be described with reference to FIGS. 11 and 13.

First, a gate insulating film 16 and a gate electrode 17 are formed on a semiconductor layer 10 using a known method as shown in FIG. 11.

Subsequently, a portion where a drain region is to be formed is covered by a mask of, for example, a resist. Thereafter, ion implantation of an impurity is performed and annealing is performed for activation, thereby forming an impurity region 12 to serve as a source region (FIG. 12).

Then, the source region 12 is masked by, for example, a resist. Thereafter, ions of an impurity are implanted to the drain region, and annealing is performed for activation, thereby forming a drain region 14 with an impurity concentration higher than that of the source region 12. The annealing for activation of the impurity region 12 to serve as the source region can be performed concurrently with the annealing for activation of the drain region 14. Thereafter, a gate sidewall 18 of an insulating material is formed on a side portion of the gate electrode 17 (FIG. 13). The gate sidewall 18 may be formed before the impurity ion implantation to form the source region 12 and the drain region 14 is performed.

Next, native oxide films on the surfaces of the source region 12 and the drain region 14 to serve as a source electrode 24 and a drain electrode 25 are removed, and an insulating material film and a ferromagnetic material film are sequentially formed as in the case of the first embodiment. Subsequently, a resist (not shown) is applied onto the semiconductor layer 10, and a resist pattern in the shape of a source electrode and a drain electrode is formed using a lithographic technique. The ferromagnetic material film and the insulating material film are patterned by RIE or milling using the resist pattern as a mask to form the source electrode 24 and the drain electrode 25. A tunnel insulating film 22 is formed between the source electrode 24 and the source region 12, and a tunnel insulating film 23 is formed between the drain electrode 25 and the drain region 14 at this time.

Finally, a contact electrode (not shown) is formed on each of the ferromagnetic layers 24, 25 and the gate electrode 17 to complete the spin MOSFET 1B.

As described above, a spin MOSFET according to the second embodiment, like that according to the first embodiment, is capable of obtaining a high MC ratio.

### Third Embodiment

A spin MOSFET according to a third embodiment will be described with reference to FIG. 14. FIG. 14 is a cross-sectional view showing a spin MOSFET 1C according to the third embodiment.

The spin MOSFET 1C according to the third embodiment is obtained by forming the tunnel insulating film 22 on the source electrode 24 side to be thicker than the tunnel insulating film 23 on the drain electrode 25 in the spin MOSFET 1 according to the first embodiment shown in FIG. 2. It is preferable that the thickness of the tunnel insulating film 22 on the source electrode 24 side be 1.1 or more times the thickness of the tunnel insulating film 23 on the drain electrode 25 side. In order to reduce the resistance, it is preferable that the thickness of the tunnel insulating film 22 on the source electrode 24 side be 2 or less times the thickness of the tunnel insulating film 23 on the drain electrode 25 side.

This structure makes the junction resistance on the source electrode 24 side greater than that on the drain electrode 25 side. As a result, the MC ratio is improved due to the field effect as the present inventors have found.

Although the junction area of the source electrode 24 in the third embodiment is smaller than that of the drain electrode 25 like that of the first embodiment, the junction areas may be equal to each other.

A giant magnetoresistance (GMR) element may be employed to form at least one of the source electrode 24 and the drain electrode 25 in the third embodiment as in the case of the modification of the first embodiment shown in FIG. 5. The GMR element is more preferable since it can also be used to switch the spin direction. A spin MOSFET with a higher MC ratio can be obtained by using the GMR element since a higher spin polarization can be maintained.

A voltage-controlled writing method using a ferroelectric material may be applied to switch the spin direction instead of the spin transfer torque method. A source electrode with the structure of the second modification of the first embodiment shown in FIG. 6 is used in this case.

The tunnel insulating films 22, 23 disposed at the interfaces between the semiconductor layer 10 and the ferromagnetic layers 24, 25 in the third embodiment shown in FIG. 14 may be omitted if the conductance mismatch between the semiconductor layer 10 and the ferromagnetic layers 24, 25 can be solved.

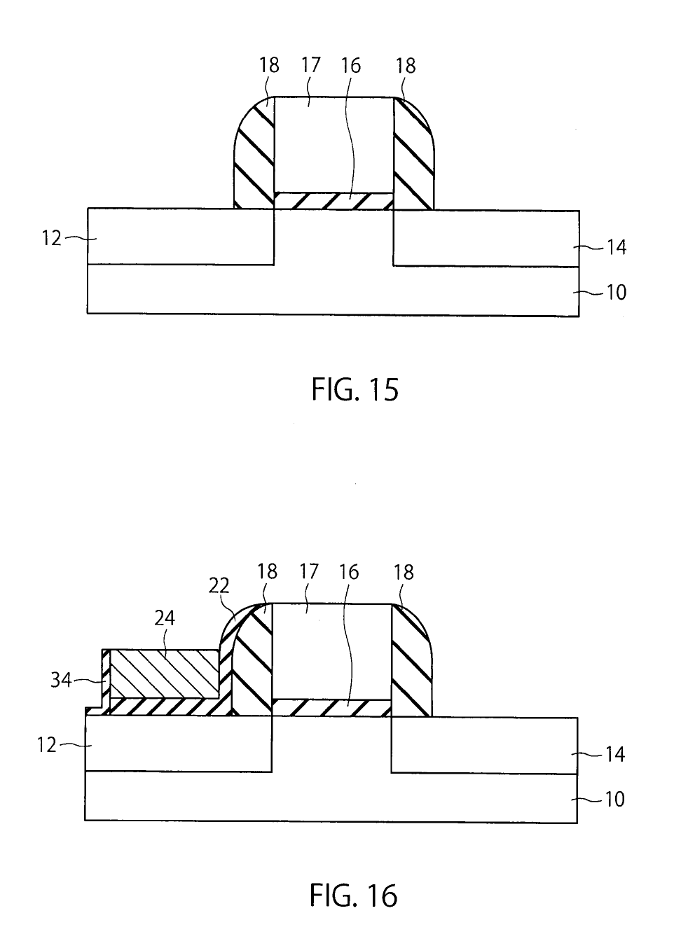

Next, a method of manufacturing the spin MOSFET 1C according to the third embodiment will be described with reference to FIGS. 15 to 17.

First, a gate insulating material film is formed on a semiconductor layer 10, and a gate electrode material film is formed on the insulating material film as shown in FIG. 15. Subsequently, the gate electrode material film and the insulating material film are patterned in the shape of a gate electrode to form a gate electrode 17 and a gate insulating film 16. Thereafter, an impurity is implanted to the semiconductor layer 10 using the gate electrode 17 as a mask and a heat treatment for activation is performed, thereby forming a source region 12 and a drain region 14. Then, a gate sidewall 18 of an insulating material is formed on a side portion of the gate electrode 17. The source region 12 and the drain region 14 may be formed by implanting an impurity to the semiconductor layer 10 after the gate sidewall 18 is formed.

Thereafter, the drain region 14 is covered by a mask of, for example, a resist. Subsequently, the native oxide film on the surface of the source region 12 is removed, and then a tunnel insulating film 22 and a ferromagnetic layer 24 are sequentially formed. A resist (not shown) is applied onto the semiconductor layer 10, and the ferromagnetic layer is removed by RIE or milling using a stepper except for the region where a source electrode 24 is to be formed. Then, a protective film 34 of SiO₂ is formed and a lift-off process is performed (FIG. 16).

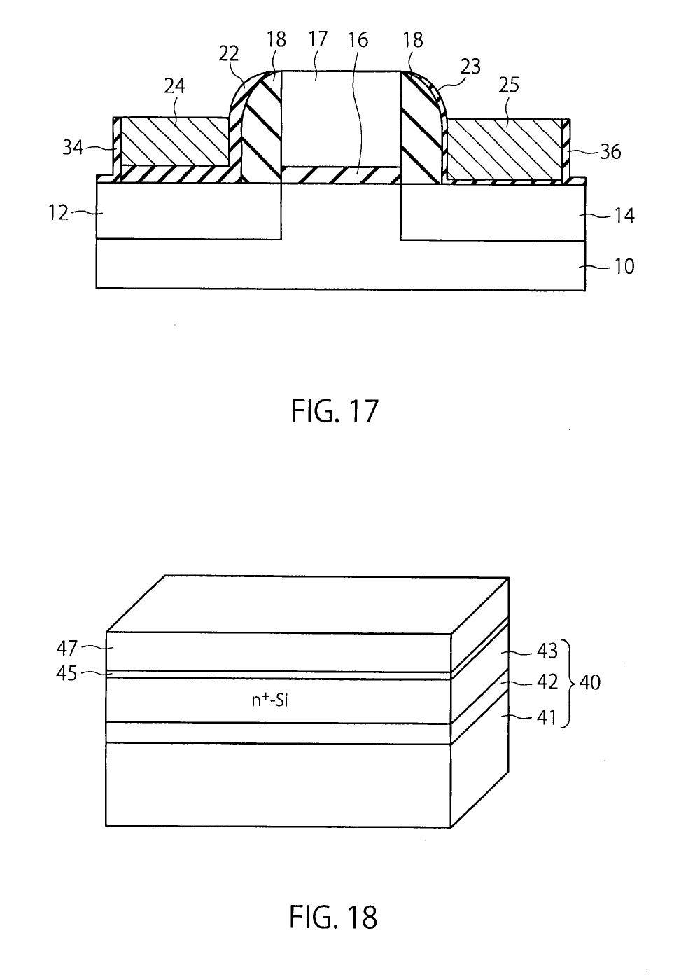

A resist (not shown) is then applied onto the semiconductor layer 10 to form a protective pattern thereon except for a region where a drain electrode is to be formed, the native oxide film on the surface of the drain region 14 is removed, and a drain electrode 25 including a tunnel insulating film 23 and a ferromagnetic layer is formed. The junction resistance of the source electrode 24 can be made greater than that of the drain electrode 25 by making the tunnel insulating film 23 thinner than the tunnel insulating film 22. Subsequently, a resist is applied onto the semiconductor layer 10, and the ferromagnetic layer except for the region where the drain electrode 25 to be formed is removed by RIE or milling using a stepper to form a SiO₂ protective film 36, and a lift-off process is performed (FIG. 17). Although the source electrode 24 is formed before the drain electrode 25 in this manufacturing method, the drain electrode 25 may be formed before the source electrode 24.

Finally, a contact electrode (not shown) is formed on each of the ferromagnetic layers 24, 25 and the gate electrode 17 to complete the spin MOSFET 1C.

As described above, the spin MOSFET according to the third embodiment is capable of obtaining a high MC ratio like the spin MOSFET according to the first embodiment.

Two or more of the embodiments and their modifications may be combined. A spin MOSFET a higher MC ratio may be obtained in this manner due to the synergistic effect of the field effect.

Examples will be described in detail below.

### Example 1

A device is produced as Example 1, and a test is performed on this device. The device is formed in the following manner. A silicon-on-insulator (SOI) substrate 40 is prepared, in which a support substrate 41, an embedded insulating film 42, and an n⁺-Si(001) layer 43 are stacked in this order. A tunnel insulating layer 45 formed of MgO having a thickness of 1 nm is disposed on the n⁺-Si(001) layer 43. A ferromagnetic layer 47 of CoFe having a thickness of 15 nm is formed on the tunnel insulating layer 45 (FIG. 18). The respective layers are formed by an ultra-high vacuum sputtering device.

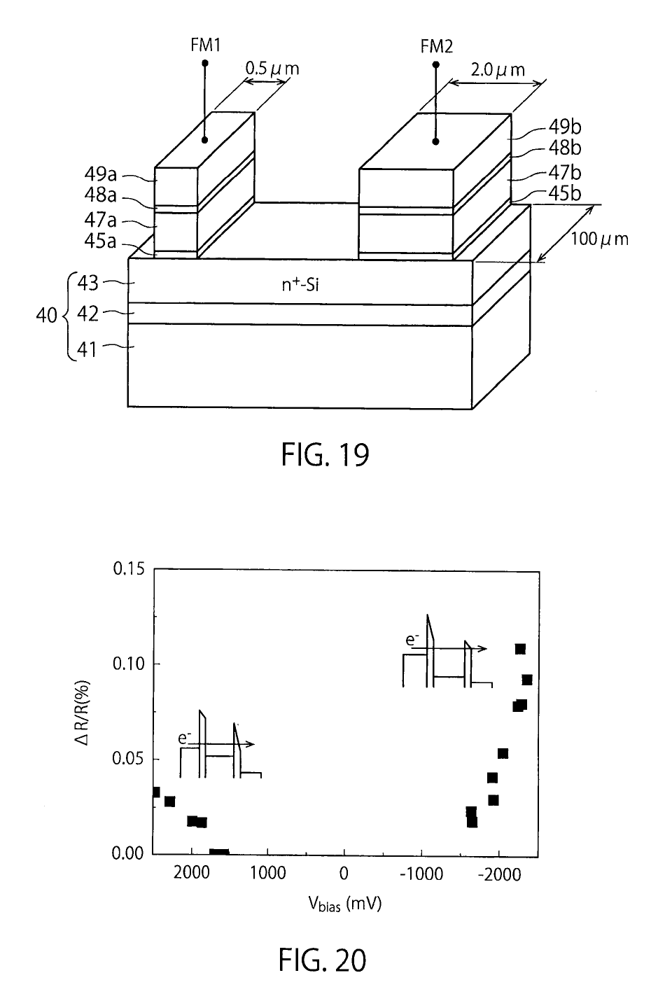

Subsequently, a resist (not shown) is applied onto the ferromagnetic layer 47, and a mask of the resist in the shape of an electrode FM1 and an electrode FM2 is formed using a lithographic technique. The ferromagnetic layer 47 and the tunnel insulating layer 45 are patterned by a milling method using this mask. A multilayer structure including a tunnel insulating layer 45a and a ferromagnetic layer 47a is formed on a region where the electrode FM1 is formed, and a multilayer structure including a tunnel insulating layer 45b and a ferromagnetic layer 47b is formed on a region where the electrode FM1 is formed (FIG. 19). Subsequently, the mask of the resist is removed, and a resist is applied again (not shown) to form another mask of a resist in a shape of a channel region by a lithographic technique. The n⁺-Si(001) layer 43 to serve as the channel is patterned by RIE using this mask. The n⁺-Si(001) layer 43 is patterned to have a width of 100 μm as shown in FIG. 19. Thereafter, a protective film of SiO₂ is formed (not shown), and a lift-off process is performed to form a protective film of SiO₂ on side portions of the n⁺-Si(001) layer 43 in the width direction (not shown). Finally, a multilayer structure including a Ti layer having a thickness of 50 nm and a Au layer having a thickness of 150 nm is formed on each of the ferromagnetic layers 47a, 47b to form upper electrodes (FIG. 19). The channel width in this state is 100 μm, the lengths of the ferromagnetic layers 47a, 47b in a direction parallel to the channel direction is 0.5 μm for the electrode FM1, and 2.0 μm for the electrode FM2 (FIG. 19).

FIG. 20 shows the plotting of the resistance difference (ΔR/R: ΔR is a difference in resistance value between the antiparallel state and the parallel state, and R is a resistance value in the antiparallel state), i.e., Local signal, relative to V_{bias}, the resistance difference varying between the electrode FM1 and the electrode FM2, on the conditions that the electrode FM1 is the source electrode and the electrode FM2 is the drain electrode, that when electrons are injected to the source electrode, V_{bias} becomes greater than 0, and that the spin directions of the electrode FM1 and the electrode FM2 are caused to be antiparallel to each other due to the influence of an external magnetic field. The barrier diagrams in FIG. 20 schematically show the directions of electrons in cases where V_{bias}<0 and V_{bias}>0, and the electric field applied to the MgO tunnel barrier.

It can be understood from FIG. 20 that when V_{bias}<0, i.e., when electrons are injected to the source electrode of the electrode FM1, the Local signal is greater. Therefore, if the electric field of the source electrode is greater than that of the drain electrode, the MC ratio is improved in an n-channel spin MOSFET.

As a result of a similar measurement performed on a p-channel spin MOSFET, it can be found that if the electric field of an electrode to which holes are injected is greater, the MC ratio is improved.

The relationship between the MC ratio and the ratio of the length of the electrode FM1 to the length of the electrode FM2 in a direction parallel to the channel direction of the ferromagnetic material (“channel length”) is calculated in a spin diffusion model considering the field effect. As a result, the MC ratio is 30% when the ratio of the length of the electrode FM1 to the length of the electrode FM2 in the channel direction is 1:1.25, and is 38% when the ratio is 1:4. Thus, it is confirmed from the numerical calculation that the MC ratio is improved if the length of the electrode FM2 in the channel direction is longer than the length of the electrode FM1 in the channel direction.

The MC ratio is improved if the junction area of the electrode FM2 relative to the junction area of the electrode FM1 is 1.1 or more. The junction area of the electrode FM2 relative to the junction area of the electrode FM1 is preferably 1.3 or more.

### Example 2

An optimum ferromagnetic material considering the field effect will be described as Example 2 below.

The present inventors have found from the evaluation of spin accumulation signals in silicon semiconductors that the density of state of a ferromagnetic material exerts an influence on the spin transfer efficiency. This means that the spin transfer torque efficiency of and the spin detection efficiency are changed by the field effect.

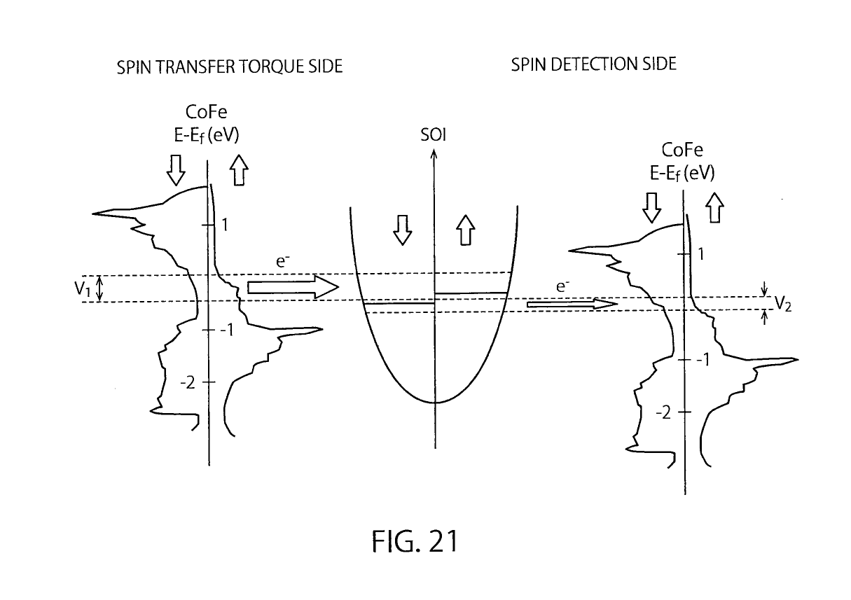

FIG. 21 schematically shows the relationship between V_{bias} and the density of state on the source electrode side and the drain electrode side of an n-channel spin MOSFET. The density of state of CoFe is used as that of a ferromagnetic material here. If is understood from FIG. 21 that in an n-channel spin MOSFET, the spin polarization estimated from the density of state in the V₁ region exerts influence on the spin transfer torque or the spin detection on the source electrode side, and the spin polarization estimated from the density of state in the V₂ region exerts influence on the spin transfer torque or the spin detection on the drain electrode side. Therefore, it is preferable that a ferromagnetic material with which the spin polarization in the V₁ region and the V₂ region becomes great be used as the electrode material of a spin MOSFET. It has also found that the MC ratio is improved as the electric field on the source electrode side becomes greater in consideration of the field effect in spin MOSFETs found by the present inventors.

Therefore, a high MC ratio can be achieved in a spin MOSFET considering the field effect if it has a device structure where the V₁ region is larger than the V₂ region. This requires a ferromagnetic material having a higher spin polarization in the V₁ region.

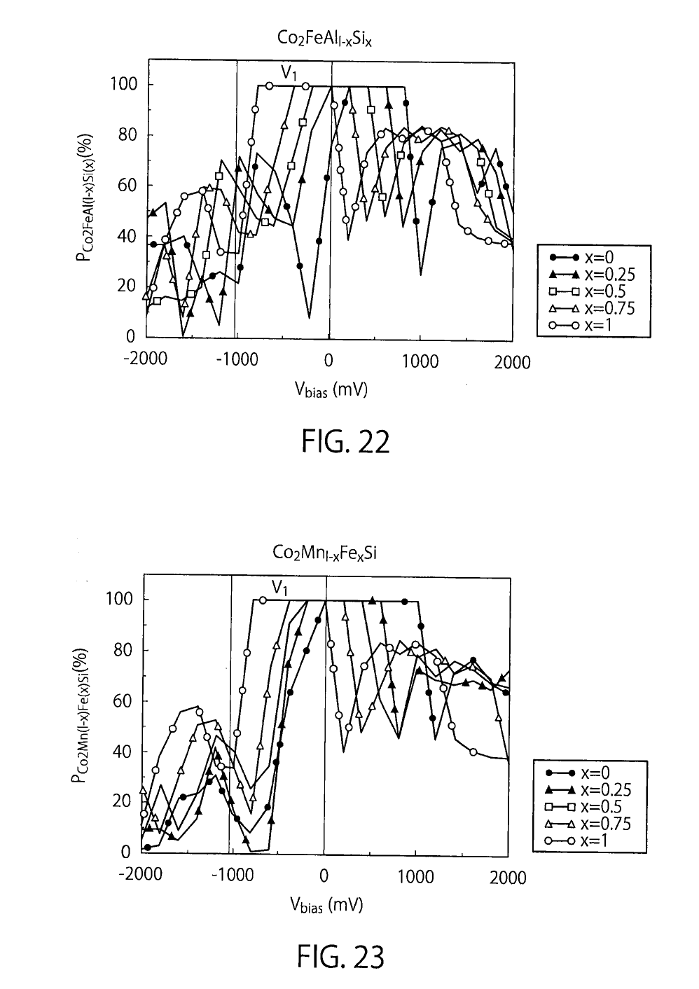

The present inventors have focused attention on Heusler alloys that are expected as half metal materials, and have calculated the spin polarization that can be estimated from the composition ratio and the density of state of each material. FIG. 22 shows the relationship between the composition ratio and the spin polarization of Co₂FeAl₁₋ₓSiₓ (0≦x≦1.0), and FIG. 23 shows that of Co₂Mn₁₋ₓFeₓSi (0≦x≦1.0). It can be understood that the dependence of spin polarization on V_{bias} changes as the composition ratio changes. The V₁ region needed when the device is used as an n-channel spin MOSFET is shown in each of FIGS. 22 and 23.

It has been found that an n-channel spin MOSFET has a high spin polarization in the V₁ region if the x composition of a magnetic material Co₂FeAl₁₋ₓSiₓ is 0.5≦x≦1.0, and that of Co₂Mn₁₋ₓFeₓSi is 0.25≦x≦1.0. This indicates that optimum ferromagnetic materials of n-channel spin MOSFETs considering the field effect are Co₂FeAl₁₋ₓSiₓ (0.5≦x≦1.0) or Co₂Mn₁₋ₓFeₓSi (0.2≦x≦1.0), and optimum materials of p-channel spin MOSFETs are Co₂FeAl₁₋ₓSiₓ (0≦x<0.5) or Co₂Mn₁₋ₓFeₓSi (0≦x<0.25).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An MOSFET comprising:
a semiconductor layer;
a source electrode and a drain electrode each including a magnetic layer provided on the semiconductor layer so as to be separated from each other, a junction resistance between the source electrode and the semiconductor layer being greater than a junction resistance between the drain electrode and the semiconductor layer;
a gate insulating film provided on a region of the semiconductor layer to serve as a channel between the source electrode and the drain electrode; and
a gate electrode provided on the gate insulating film,
wherein the MOSFET is of n-channel type, and the source electrode and the drain electrode contain a magnetic material in which a gap energy between a Fermi surface and a valence band maximum of a valence band is greater than a gap energy between the Fermi surface and a conduction band minimum of a conduction band, or
wherein the MOSFET is of p-channel type, and the source electrode and the drain electrode contain a magnetic material in which a gap energy between a Fermi surface and a valence band maximum of a valence band is less than a gap energy between the Fermi surface and a conduction band minimum of a conduction band.

2. The MOSFET according to claim 1, wherein the MOSFET is of n-channel type, and each of the source electrode and the drain electrode contains at least one magnetic material selected from the group consisting of Co₂FeAl₁₋ₓSiₓ (0.5≦x≦1.0) and Co₂Mn₁₋ₓFeₓSi (0.25≦x≦1.0), or
wherein the MOSFET is of p-channel type, and each of the source electrode and the drain electrode contains at least one magnetic material selected from the group consisting of Co₂FeAl₁₋ₓSiₓ (0≦x<0.5) and Co₂Mn₁₋ₓFeₓSi (0≦x<0.25).

3. The MOSFET according to claim 1, wherein a junction area of the drain electrode is 10% or more greater than a junction area of the source electrode, and a length of the source electrode is shorter than a length of the drain electrode in a direction parallel to a channel direction.

4. The MOSFET according to claim 1, wherein an impurity region with an impurity concentration of 1×10¹⁷ to 3×10²⁰/cm³ is provided in the semiconductor layer below the source electrode.

5. The MOSFET according to claim 1, wherein a first tunnel insulating film is provided between the source electrode and the semiconductor layer, and a second tunnel insulating film is provided between the drain electrode and the semiconductor layer, the first tunnel insulating film being 10% or more thicker than the second tunnel insulating film.

6. The MOSFET according to claim 5, wherein the first tunnel insulating film and the second tunnel insulating film are formed of at least one oxide selected from the group consisting of an alkaline earth oxide with a NaCl structure, Al₂O₃, MgAl₂O₄, SiO₂, ZnO, (MgₓZn₁₋ₓ)O, AlNx, HfO₂, Zr₂O₃, Cr₂O₃, TiO₂, and SrTiO₃.

7. The MOSFET according to claim 1, wherein at least one of the source electrode and the drain electrode is a GMR element including a first magnetic film provided on the semiconductor layer, a nonmagnetic metal film provided on the first magnetic film, and a second magnetic film provided on the nonmagnetic metal film.

8. The MOSFET according to claim 1, further comprising a ferroelectric layer provided on a side portion of the source electrode, and a nonmagnetic conductive layer provided on the ferroelectric layer on an opposite side to the source electrode,
wherein a magnetization direction of the magnetic layer in the source electrode is switched by applying a voltage between the source electrode and the nonmagnetic conductive layer, or between the semiconductor layer and the nonmagnetic conductive layer.

9. An MOSFET comprising:
a semiconductor layer;
a source electrode and a drain electrode each including a magnetic layer provided on the semiconductor layer so as to be separated from each other, a junction resistance between the source electrode and the semiconductor layer being greater than a junction resistance between the drain electrode and the semiconductor layer;
a gate insulating film provided on a region of the semiconductor layer to serve as a channel between the source electrode and the drain electrode; and
a gate electrode provided on the gate insulating film,
wherein the MOSFET is of n-channel type, and the source electrode and the drain electrode contain at least one magnetic material selected from the group consisting of Co₂FeAl₁₋ₓSiₓ (0.5≦x≦1.0), Co₂Mn₁₋ₓFeₓSi (0.25≦x≦1.0), Co₂MnₓTi₁₋ₓGe (0≦x≦0.5), Co₂Cr₁₋ₓFeₓAl (0.75≦x≦1.0), Mn₂CoSn, and Co₂TiAl, or
wherein the MOSFET is of p-channel type, and the source electrode and the drain electrode contain at least one magnetic material selected from the group consisting of Co₂FeAl₁₋ₓSiₓ (0≦x<0.5), Co₂Mn₁₋ₓFeₓSi (0≦x<0.25), Co₂MnₓTi₁₋ₓGe (0.5<x≦1.0), Co₂Cr₁₋ₓFeₓAl (0≦x<0.75), and CoFeMnX (where X is at least one element selected from the group consisting of Al, Si, Ge, and Ga).

10. The MOSFET according to claim 9, wherein the MOSFET is of n-channel type, and the source electrode and the drain electrode contain at least one magnetic material selected from the group consisting of Co₂FeAl₁₋ₓSiₓ (0.5≦x≦1.0) and Co₂Mn₁₋ₓFeₓSi (0.25≦x≦1.0); or
wherein the MOSFET is of p-channel type, and the source electrode and the drain electrode contain at least one magnetic material selected from the group consisting of Co₂FeAl₁₋ₓSiₓ (0≦x<0.5) and Co₂Mn₁₋ₓFeₓSi (0≦x<0.25).

11. The MOSFET according to claim 9, wherein a junction area of the drain electrode is 10% or more greater than a junction area of the source electrode, and a length of the source electrode is shorter than a length of the drain electrode in a direction parallel to a channel direction.

12. The MOSFET according to claim 9, wherein an impurity region with an impurity concentration of 1×10¹⁷ to 3×10²⁰/cm³ is disposed in the semiconductor layer below the source electrode.

13. The MOSFET according to claim 9, wherein a first tunnel insulating film is provided between the source electrode and the semiconductor layer, and a second tunnel insulating film is provided between the drain electrode and the semiconductor layer, the first tunnel insulating film being 10% or more thicker than the second tunnel insulating film.

14. The MOSFET according to claim 13, wherein the first tunnel insulating film and the second tunnel insulating film are formed of at least one oxide selected from the group consisting of an alkaline earth oxide with a NaCl structure, Al₂O₃, MgAl₂O₄, SiO₂, ZnO, (MgₓZn₁₋ₓ)O, AlNx, HfO₂, Zr₂O₃, Cr₂O₃, TiO₂, and SrTiO₃.

15. The MOSFET according to claim 9, wherein at least one of the source electrode and the drain electrode is a GMR element including a first magnetic film provided on the semiconductor layer, a nonmagnetic metal film provided on the first magnetic film, and a second magnetic film provided on the nonmagnetic metal film.

16. The MOSFET according to claim 9, further comprising a ferroelectric layer provided on a side portion of the source electrode, and a nonmagnetic conductive layer provided on the ferroelectric layer on an opposite side to the source electrode,
wherein a magnetization direction of the magnetic layer in the source electrode is switched by applying a voltage between the source electrode and the nonmagnetic conductive layer, or between the semiconductor layer and the nonmagnetic conductive layer.
